(19) United States
(12) Patent Application Publication
(10) Pub. No.: US 2010/0154863 A1
(43) Pub. Date: Jun. 24, 2010

(54) CONCENTRATOR SOLAR CELL MODULES WITH LIGHT CONCENTRATING ARTICLES COMPRISING IONOMERIC MATERIALS

(75) Inventors: ALISON MARGARET ANNE BENNETT, Wilmington, DE (US); Philip L. Boydell, Challex (FR); Alexander Zak Bradley, Drexel Hill, PA (US); Richard Allen Hayes, Beaumont, TX (US); Steven C. Pesek, Orange, TX (US); George Wyatt Prejean, Orange, TX (US); Jose Manuel Rodriguez-Parada, Hockessin, DE (US); Lois A. Santopietro, West Chester, PA (US); W. Alexander Shaffer, Orange, TX (US); Charles Anthony Smith, Vienna, WV (US); Roger Harquail French, Wilmington, DE (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E.I. DU PONT DE NEMOURS AND COMPANY, Wilmington, DE (US)

(21) Appl. No.: 12/626,046

(22) Filed: Nov. 25, 2009

Related U.S. Application Data
(60) Provisional application No. 61/118,381, filed on Nov. 26, 2008.

(51) Int. Cl. H01L 31/052

(52) U.S. Cl. 136/246

(57) ABSTRACT

A concentrator solar cell module comprises at least one solar cell and at least one light concentrating article. The at least one light concentrating article is capable of concentrating about 1.02 to about 2000 sun equivalents of solar energy onto the solar cell(s) and comprises an ionomer composition. The ionomer composition comprises or is produced from an ionomer that has a temperature of onset of creep that is significantly greater than its peak melting temperature.

### FIELD OF THE INVENTION

The invention relates to concentrator solar cell modules comprising at least one light concentrating article. The light concentrating article(s) comprise or are produced from an ionomeric composition, which in turn comprises or is produced from an ionomer.

### BACKGROUND OF THE INVENTION

Several patents and publications are cited in this description in order to more fully describe the state of the art to which this invention pertains. The entire disclosure of each of these patents and publications is incorporated by reference herein.

The use of solar cells, which produce electricity from visible light, is rapidly expanding because of a need for renewable and sustainable energy resources. Solar cells can be categorized into two types, bulk or wafer-based solar cells and thin film solar cells. A comprehensive description of solar cells and photovoltaic devices appears in the Handbook of Photovoltaic Science and Engineering by Antonio Luque and Steven Hegedus, published by John Wiley and Sons (2003, Hoboken, N.J.).

In particular, light concentrating solar cell modules improve the efficiency of typical solar cell modules by increasing the amount of light that is gathered and cast on the solar cell. These concentrator solar cell modules include a light concentrating article, such as a reflective or refractive optical system, to capture the sunlight shining on a given area and cast it onto solar cell(s) that have a smaller surface area.

Increasing the amount of light that is cast on each solar cell increases the amount of electricity that the solar cell produces. For example, a concentrator solar cell module with a relatively low efficiency is capable of providing a solar concentration factor of about 1.02 to 10 suns, while a concentrator solar cell module with a relatively high efficiency can provide a solar concentration factor of about 200 suns or higher.

Moreover, light concentrating articles are generally less costly than solar cells, which typically are made of silicon or of highly efficient III-V materials such as GaAs. Therefore, the use of concentrator solar cell modules also provides an economic efficiency.

Several light concentrating articles and concentrator solar cell modules have been developed and described in the literature including, without limitation, the following. First, encapsulant layers with embossed grooves to redirect light into solar cells are described in U.S. Pat. Nos. 5,110,370; 5,228,926; and 5,554,229. Converging lenses are described in U.S. Pat. Nos. 4,053,327; 4,188,238; 4,253,880; 4,331,829; 4,379,202; 4,836,861; 5,096,505; 5,116,427; 5,167,724; 5,123,968; 6,111,190; 6,700,054; in U.S. Patent Appln. Publn. No. 2008/0087323; in European Patent No. 0 581 889; and in Intl. Patent Appln. Publn. No. WO2007/044384. Concentrating coverglasses are described in U.S. Pat. Nos. 5,959,787; 6,091,020; 2006/0283497; and in European Patent No. 0 255 900. Fresnel lenses are described in U.S. Pat. Nos. 3,125,091; 4,545,366; 4,848,319; 5,118,361; 5,217,539; 5,496,414; 5,498,297; 5,578,139; in U.S. Patent Appln. Publn. Nos. 2003/0201007 and 2004/0112424; in European Patent No. 1 892 771; and in Intl. Patent Appln. Publn. Nos. WO 2006/120475 and WO 2007/041018. In addition, U.S. Pat. Nos. 5,344,497; 5,505,789; and 6,075,200 describe the use of linear arched Fresnel line focused lenses in concentrator solar cell modules. U.S. Pat. Nos. 4,069,812 and 6,031,179 describe the use of curved prismatic Fresnel-type lenses in concentrator solar cell modules. U.S. Patent Appln. Publn. No. 2003/0075212 describes the use of a Fresnel-type refractive concentrator in series with parabolic reflector concentrators. U.S. Patent Appln. Publn. No. 2005/0081908 describes the use of concentrator lenslets for a miniature photovoltaic device array. Finally, integral concentrator solar cell modules incorporating converging lenses are described in U.S. Patent Appln. Publn. Nos. 2005/0081909; 2006/0283495; 2007/0056626; 2008/0053515; and 2007/0095386; and in Intl. Patent Appln. Publn. No. WO 2007/093422.

The light concentrating articles used in the concentrator solar cell modules are often made of glass or plastics, such as polycarbonates and acrylics such as poly(methyl methacrylate). For example, the use of acrylics, polystyrenes, polycarbonates, or methacrylate styrene copolymers as materials for Fresnel lenses is described in U.S. Pat. Nos. 4,069,812; 4,188,238; 4,545,366; and 5,498,297, and the use of acrylics as materials for converging lenses is described in U.S. Pat. No. 6,700,054. A comprehensive description of these optical plastics and their properties appears in the “Handbook of Optical Materials” by M. Weber, published by the CRC Press (Boca Raton, 2002).

It is noted, however, that glass and acrylics cannot easily be formed into light concentrating articles through low cost melt processes. In addition, the useful life of a solar cell is about 20 to 30 years. Light concentrating articles made of polycarbonate, however, often fail to endure environmental stresses, such as weathering, for this period of time. Mechanical failures, such as excessive deformation under stress, are also problematic. Therefore, the deterioration of polycarbonates and other thermoplastic materials limits the useful life of the solar cell modules.

Accordingly, there remains a need to develop new materials for use in the light concentrating articles that are included in concentrator solar cell modules. Desirably, these materials can be formed easily by melt processing. Also desirably, the light concentrating article is stable for a period of time that does not limit the useful life of the solar cell module.

### SUMMARY OF THE INVENTION

Provided herein is a concentrator solar cell module comprising at least one solar cell and at least one light concentrating article. The at least one light concentrating article comprises an ionomer composition and is capable of concentrating about 1.02 to about 2000 sun equivalents of solar energy onto the solar cells. The ionomer composition comprises or is produced from an ionomer that has a temperature of onset of creep that is significantly greater than its peak melting temperature.

These and various other advantages and features of novelty that characterize the invention are pointed out with particularity in the claims annexed hereto and forming a part hereof. For a better understanding of the invention, its advantages, and the objects obtained by its use, however, reference should be made to the drawings which form a further part hereof, and to the accompanying descriptive matter, in which there is illustrated and described a preferred embodiment of the invention.

### BRIEF DESCRIPTION OF THE DRAWINGS

FIG. 1 is a view in cross-section of a concentrator solar cell module.

FIG. 2 is a perspective view of a second concentrator solar cell module.

FIG. 3 is a perspective view of a third concentrator solar cell module.

### DETAILED DESCRIPTION OF THE INVENTION

The following definitions apply to the terms as used throughout this specification, unless otherwise limited in specific instances.

The technical and scientific terms used herein have the meanings that are commonly understood by one of ordinary skill in the art to which this invention belongs. In case of conflict, the present specification, including the definitions herein, will control.

The term “complementarily”, as used herein, refers to numbers that sum to 100%.

As used herein, the terms “comprises,” “comprising,” “includes,” “including,” “containing,” “characterized by,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The transitional phrase “consisting of” excludes any element, step, or ingredient not specified in the claim, closing the claim to the inclusion of materials other than those recited except for impurities ordinarily associated therewith. When the phrase “consists of” appears in a clause of the body of a claim, rather than immediately following the preamble, it limits only the element set forth in that clause; other elements are not excluded from the claim as a whole.

The transitional phrase “consisting essentially of” limits the scope of a claim to the specified materials or steps and those that do not materially affect the basic and novel characteristic(s) of the claimed invention. A ‘consisting essentially of’ claim occupies a middle ground between closed claims that are written in a ‘consisting of’ format and fully open claims that are drafted in a ‘comprising’ format. Optional additives as defined herein, at a level that is appropriate for such additives, and minor impurities are not excluded from a composition by the term “consisting essentially of”.

When a composition, a process, a structure, or a portion of a composition, a process, or a structure, is described herein using an open-ended term such as “comprising,” unless otherwise stated the description also includes an embodiment that “consists essentially of” or “consists of” the elements of the composition, the process, the structure, or the portion of the composition, the process, or the structure.

The articles “a” and “an” may be employed in connection with various elements and components of compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

The term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such.

The term “or”, as used herein, is inclusive; that is, the phrase “A or B” means “A, B, or both A and B”. Exclusive “or” is designated herein by terms such as “either A or B” and “one of A or B”, for example.

In addition, the ranges set forth herein include their endpoints unless expressly stated otherwise. Further, when an amount, concentration, or other value or parameter is given as a range, one or more preferred ranges or a list of upper preferable values and lower preferable values, this is to be understood as specifically disclosing all ranges formed from any pair of any upper range limit or preferred value and any lower range limit or preferred value, regardless of whether such pairs are separately described. The scope of the invention is not limited to the specific values recited when defining a range.

When materials, methods, or machinery are described herein with the term “known to those of skill in the art”, “conventional” or a synonymous word or phrase, the term signifies that materials, methods, and machinery that are conventional at the time of filing the present application are encompassed by this description. Also encompassed are materials, methods, and machinery that are not presently conventional, but that will have become recognized in the art as suitable for a similar purpose.

Unless stated otherwise, all percentages, parts, ratios, and like amounts, are defined by weight.

As used herein, the term “copolymer” refers to polymers comprising copolymerized units resulting from copolymerization of two or more comonomers. In this connection, a copolymer may be described herein with reference to its constituent comonomers or to the amounts of its constituent comonomers, for example “a copolymer comprising ethylene and 15 weight % of acrylic acid”, or a similar description. Such a description may be considered informal in that it does not refer to the comonomers as copolymerized units; in that it does not include a conventional nomenclature for the copolymer, for example International Union of Pure and Applied Chemistry (IUPAC) nomenclature; in that it does not use product-by-process terminology; or for another reason. As used herein, however, a description of a copolymer with reference to its constituent comonomers or to the amounts of its constituent comonomers means that the copolymer contains copolymerized units (in the specified amounts when specified) of the specified comonomers. It follows as a corollary that a copolymer is not the product of a reaction mixture containing given comonomers in given amounts, unless expressly stated in limited circumstances to be such.

The term “dipolymer” refers to polymers consisting essentially of two monomers, and the term “terpolymer” refers to polymers consisting essentially of three monomers.

The term “acid copolymer” as used herein refers to a polymer comprising copolymerized units of an α-olefin, an α,β-ethylenically unsaturated carboxylic acid, and optionally other suitable comonomer(s), such as an α,β-ethylenically unsaturated carboxylic acid ester.

Finally, the term “ionomer” as used herein refers to a polymer that comprises ionic groups that are carboxylates associated with cations, for example, ammonium carboxylates, alkali metal carboxylates, alkaline earth carboxylates, transition metal carboxylates and/or mixtures of such carboxylates. Such polymers are generally produced by partially or fully neutralizing the carboxylic acid groups of precursor or parent polymers that are acid copolymers, as defined herein, for example by reaction with a base. An example of an ionomer described herein is a zinc/sodium mixed ionomer (or zinc/sodium neutralized mixed ionomer), for example a copolymer of ethylene and methacrylic acid wherein all or a portion of the carboxylic acid groups of the copolymerized methacrylic acid units are in the form of zinc carboxylates and sodium carboxylates.

Finally, the term “solar cell”, as used herein, refers to any article that is capable of converting light into electrical energy; and the term “light concentrating article”, as used herein, refers to any optical system that is capable of capturing the light shining on a larger area and casting, directing, refracting or focusing the light onto a smaller area.

Provided herein are concentrator solar cell modules comprising one or more light concentrating articles and one or a plurality of solar cells positioned in such a way that light is concentrated on the solar cell(s) by the light concentrating article(s). The light concentrating articles comprise an ionomer composition. The solar cells may be part of a simpler solar cell module that is incorporated into the concentrator solar cell module. Suitable solar cell modules and concentrator solar cell modules are described in the Handbook of Photovoltaic Science and Engineering, cited above.

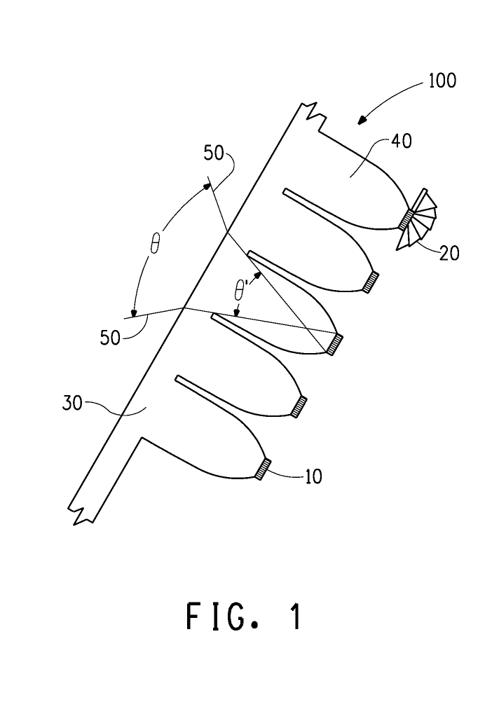

Referring now to the drawings, wherein like reference numerals designate corresponding structure throughout the views, and referring in particular to FIG. 1, one suitable concentrator solar cell module 100 comprises one or more solar cells 10. The solar cells 10 may optionally be equipped with heat sinks 20. The heat sink 20 depicted in FIG. 1 comprises heat-conductive fins, typically made of metal, whose large surface area increases the efficiency with which heat is transferred to the atmosphere. Other forms of heat sink may be used in solar cell module 100, for example, cooling water or an air flow.

Still referring to FIG. 1, solar cell module 100 further comprises a substrate 30 and at least one lens 40. The lens 40 is a light concentrating article that may be applied to the substrate 30, for example by an adhesive or by mechanical means, such as one or more clamps or a frame. Alternatively, the lens 40 and the substrate 30 may be formed integrally. Suitable materials for the lens and the substrate are transparent and stable under the conditions of operations and the period of use of solar cell module 100. When the substrate 30 and the lens 40 are not formed integrally, glass is a preferred material for the substrate 30.

Further depicted in FIG. 1 are light rays 50, which in turn illustrate the angle θ of incoming light that is cast on solar cell 10 by lens 40. Angle θ is clearly larger than angle θ′, the angle of incoming light that would be cast on solar cell 10 in the absence of lens 40. In fact, solar cell module 100 is designed to provide a relatively low factor of light concentration. For example, a solar cell module having this structure or a similar structure is expected to increase the light shining on its solar cells by a factor of between 1.01 and 10.

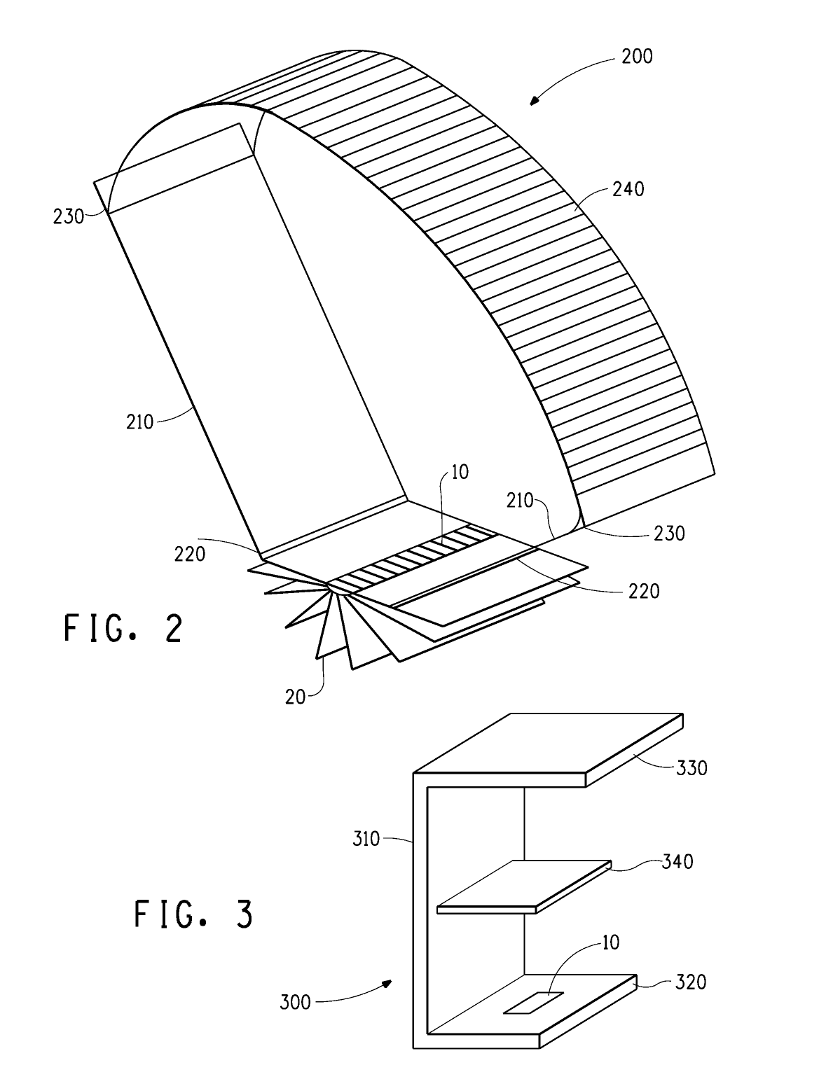

Turning now to FIG. 2, depicted is a second concentrator solar cell module 200, also comprising one or more solar cells 10 and an optional heat sink 20 that may also comprise fins as depicted, cooling water, air flow or any other suitable form of heat removal. Solar cell module 200 further comprises a lens 240, here depicted as a Fresnel lens, preferably a flexible Fresnel lens, that is held in place by one or more supports 210. Preferred supports 210 are made of rigid materials, such as, for example, metal, plastic, wood or glass.

The lens 240 is a light concentrating article. Supports 210 are connected to the solar cells 10, directly or indirectly, via a junction 220. In addition, supports 210 are connected to the lens 240, directly or indirectly, via a second junction 230. Other configurations for a solar cell of this type are possible. For example, solar cells 10 might be mounted on the floor of a rectangular prism whose four walls function as supports 210 and whose upper surface is replaced by lens 240.

Solar cell module 200 is designed to provide an intermediate factor of light concentration. For example, a solar cell module having this structure or a similar structure is expected to increase the light shining on its solar cells by a factor of between 10 and 200. In order to attain this level of efficiency, the solar cell module 200 might be made to track the path of the sun, for example with a one or two axis tracking system.

Turning now to FIG. 3, a third concentrator solar cell module 300 comprises one or more solar cells 10 and, optionally, a heat sink (not depicted). The solar cells 10 are affixed permanently or interchangeably to a mount 320, which is connected to a support structure 310. Preferred support structures 310 are made of rigid materials, such as, for example, metal, plastic, wood or glass. The inner surface of support structure 310 may preferably be a reflective surface, so as to cast more light upon the solar cells 10. Also connected to the support structure 310 are a primary optical system 330 and a secondary optical system 340. At least one of the primary optical system 330 and the secondary optical system 340 are light concentrating articles. Preferably, however, both the primary optical system 330 and the secondary optical system 340 are light concentrating articles. In addition, the secondary optical system 340 is typically in direct contact with the solar cells 10.

Solar cell module 300 is designed to provide a high factor of light concentration. For example, a solar cell module having this structure or a similar structure is expected to increase the light shining on its solar cells by a factor of between 200 and 2000. In order to attain this level of efficiency, the solar cell module 300 might be made to track the path of the sun, for example with a high precision two axis tracking system.

Suitable solar cells for use in the concentrator solar cell modules described herein include, but are not limited to, wafer-based solar cells and thin film solar cells When multiple solar cells are used in the module, it is preferred that the solar cells be electrically interconnected. Multi-junction solar cells comprising a combination of two or more of the solar cell materials set forth below may also be used in the concentrator solar cell modules.

Monocrystalline silicon (c-Si), poly-crystalline silicon (poly-Si) or multi-crystalline silicon (mc-Si) and ribbon silicon are the materials used most commonly in forming wafer-based solar cells. In addition, highly efficient III-V solar cell materials such as GaAs may be used in wafer-based solar cells. Solar cell modules derived from wafer-based solar cells often comprise a series of self-supporting wafers (or cells) that are soldered together. The wafers generally have a thickness of between about 180 and about 240 μm. Such a panel of solar cells is called a solar cell layer and it may further comprise electrical wirings such as cross ribbons that connect the individual cell units and bus bars that have one end connected to the cells and the other exiting the module. The solar cell layer is then further laminated to encapsulant layer(s) and protective layer(s) to form a weather resistant module that may be used for up to 25 to 30 years. In general, a solar cell module derived from wafer-based solar cell(s) comprises, in order of position from the front light-receiving side to the back non-light-receiving side: (1) an incident layer, (2) a front (or incident) encapsulant layer, (3) a solar cell layer, (4) a back encapsulant layer, and (5) a backing layer.

Thin film solar cells are commonly formed from materials that include amorphous silicon (a-Si), microcrystalline silicon (μc-Si), cadmium telluride (CdTe), copper indium selenide (CuInSe₂ or CIS), copper indium/gallium diselenide (CuInₓGa₍₁₋ₓ₎Se₂ or CIGS), light absorbing dyes, and organic semiconductors. Some suitable thin film solar cells are described in U.S. Pat. Nos. 5,507,881; 5,512,107; 5,948,176; 5,994,163; 6,040,521; 6,137,048; and 6,258,620; and in U.S. Patent Appln. Publn. Nos. 2007/0298590; 2007/0281090; 2007/0240759; 2007/0232057; 2007/0238285; 2007/0227578; 2007/0209699; and 2007/0079866, for example.

Thin film solar cells with a thickness of typically less than 2 μm are produced by depositing semiconductor layers onto a superstrate or substrate formed of glass or a flexible film. During manufacture, it is common to include a laser scribing sequence that enables the adjacent cells to be directly interconnected in series, with no need for further solder connections between cells. Nevertheless, as with wafer cells, the thin film solar cell layer may further comprise electrical wirings such as cross ribbons and bus bars. Similarly, the thin film solar cells are further laminated to other encapsulant and protective layers to produce a weather resistant and environmentally robust module.

Depending on the sequence in which the multi-layer deposition is carried out, the thin film solar cells may be deposited on a superstrate that ultimately serves as the incident layer in the final module, or the cells may be deposited on a substrate that ends up serving as the backing layer in the final module. Therefore, a solar cell module derived from thin film solar cells may have one of two types of construction. The first type includes, in order of position from the front light-receiving side to the back non-light-receiving side, (1) a solar cell layer comprising a superstrate and a layer of thin film solar cell(s) deposited thereon at the non-light-receiving side, (2) a (back) encapsulant layer, and (3) a backing layer. The second type may include, in order of position from the front light-receiving side to the back non-light-receiving side, (1) an incident layer, (2) a (front or incident layer) encapsulant layer, (3) a solar cell layer comprising a layer of thin film solar cell(s) deposited on a substrate at the light-receiving side thereof.

Light concentrating articles suitable for use in the concentrator solar cell modules described herein include any optical article that is capable of providing a solar concentration of about 1.02 or 1.04 to about 2000, preferably about 1.5 to about 1700 suns. In addition, the light concentrating article comprises the ionomer composition described below. More specifically, one or more parts of the light concentrating article, or the light concentrating article as whole, comprises or is prepared from the ionomer composition. One preferred light concentrating article is capable of providing a solar concentration of about 2 to about 10 suns and is useful in a low efficiency concentrator solar cell module. Another preferred light concentrating article is capable of providing a solar concentration of about 200 suns or higher, or about 500 to about 1000 suns, and is useful in a high efficiency concentrator solar cell module.

The light concentrating articles may have any form. For example, the light concentrating articles may be in the form of a reflective optical system, or a refractive optical system, or an optical system that acts by both reflection and refraction. For example, the light concentrating article may be in the form of a reflective optical system comprising a reflective mirror, a reflective parabaloid, a reflective dish, or a linear parabolic trough. Alternatively, the light concentrating article may be in the form of a refractive optical system comprising a refractive lens or a secondary light concentrating article, such as a dichroic filter.

The refractive lens may be derived from imaging optics or non-imaging optics. Further, the refractive lens may be a shaped incident encapsulant layer, a cover slide comprising a converging lens, a cover glass comprising a converging lens, a converging lens, a simple lens, a complex lens, a biconvex lens, a plano-convex lens, a positive meniscus lens, a plano-concave lens, an aspheric lens, an inflatable lens, a Fresnel lens, a linear Fresnel lens, a linear arched Fresnel lens, a point focus Fresnel lens, a segmented Fresnel lens, or a combination of two or more of any of these configurations.

Moreover, all or a portion of the light concentrating article may further comprise an antireflective coating. In particular, the surface of the light concentrating article may be partially or completely coated with an antireflective coating. It may be particularly desirable to provide refractive lenses with an antireflective coating. Suitable antireflective coatings may be formed of a material selected from MgF₂, fluoropolymers, fluoroelastomers, and mixtures of two or more of these materials. Examples of suitable antireflective coatings are described in U.S. Provisional Appln. Nos. 60/991,294, filed on Nov. 30, 2007 (Attorney Docket No. FL0448); 61/015,063, -074 and -080, filed on Dec. 19, 2007 (Attorney Docket Nos. FL0461, FL0419, and FL0458); U.S. patent application Ser. Nos. 11/888,382 and -383, filed on Aug. 1, 2007 (Attorney Docket Nos. FL0403 and FL0404); in other U.S. patent applications filed by Jose Manuel Rodriguez-Parada inter alia or Kostantinos Kourtakis inter alia, including U.S. Provisional Appln. Nos. 60/873,861, filed on Dec. 8, 2006 (Attorney Docket No. CL3613); and 61/139,657 and -661, filed on Dec. 22, 2008 (Attorney Docket Nos. CL4279 and CL4281); in the U.S. and international applications that claim priority to the above-mentioned applications; and in the references cited in the above-mentioned applications.

Also preferably, reflective optical systems may be metallized, polished, or treated by other means to enhance the amount of light that is reflected onto the solar cells. Suitable conditions and apparatus for metallizing objects comprising ionomer compositions are described in U.S. patent application Ser. Nos. 12/077,307, filed on Mar. 17, 2008, and 12/511,678, filed on Jul. 29, 2009 (Attorney Docket Nos. AD7463 and PP0022). Reflective optical systems may also be produced from ionomer compositions that comprise reflecting fillers, such as titanium dioxide, glass beads, or aluminum flake, for example.

Significantly, the light concentrating article may be used on the light-receiving side of the concentrator solar cell module, which may be the front side, the back side, or both the back and front sides of the module. Also significantly, the light concentrating article may be used in concentrator solar cell modules that also include glass or one or more other front sheets. Alternatively, the light concentrating article itself may be used as the back or front sheet of the concentrator solar cell module.

It is apparent that the light concentrating article will have a thickness, dimensions and a type of shape, such as concave or convex, segmented or non-segmented, for example. These properties are determined in accord with well-known optical principles and are tailored to the requirements of the desired concentrator solar cell. In particular, those of skill in the art are able to determine an appropriate focal length of a convex lens and to identify a material with an appropriate index of refraction to provide the desired solar concentration factor in a concentrator solar cell module having a particular set of design requirements, such as size and energy output, for example. See the “Handbook of Optical Materials”, cited above.

One preferred light concentrating article comprises an airtight enclosure formed by sealing a transparent cone half with a reflector half, as described in U.S. Pat. No. 4,177,083. The transparent cone half is prepared from the ionomer composition described herein. The two halves may be sealed by fusion, for example.

Another preferred light concentrating article comprises a transparent block having a planar incident surface and a curved reflective surface opposite the incident surface, as described in U.S. Pat. No. 4,440,153. The transparent block is prepared from the ionomer composition described herein.

Yet another preferred light concentrating article comprises a shaped incident layer encapsulant layer, as described in U.S. Pat. Nos. 5,110,370; 5,228,926; and 5,554,229. The shaped incident layer encapsulant layer is prepared from the ionomer composition described herein.

Yet another preferred light concentrating article comprises a cover slide or coverglass as described in U.S. Pat. Nos. 4,053,327; 4,379,202; 5,959,787; 6,091,020; 2006/0283497; and European Patent No. 0 255 900. The cover slide or coverglass is prepared from the ionomer composition described herein.

Yet another preferred light concentrating article comprises a converging lens as described in U.S. Pat. Nos. 4,188,238; 4,253,880; 4,331,829; 4,836,861; 5,096,505; 5,116,427; 5,123,968; 5,167,724; 6,700,054; in U.S. Patent Appln Publn. Nos. 2005/0081908 and 2008/0087323; in European Patent No. 0 581 889; and in Intl. Patent Appln Publn. Nos. WO2007/044384. The converging lens is prepared from the ionomer composition described herein.

Yet another preferred light concentrating article comprises a textured front or back sheet as described in U.S. patent application Ser. Nos. 12/264,986, filed on Nov. 5, 2008 (Attorney Docket No. CL4382). The textured front or back sheet is prepared from the ionomer composition described herein.

Yet another preferred light concentrating article comprises an inflatable lens as described in U.S. Pat. Nos. 3,125,091 and 6,111,190. The inflatable lens is prepared from the ionomer composition described herein.

Yet another preferred light concentrating article comprises a linear arched Fresnel lens that may include a plurality of linear prisms, as described in U.S. Pat. Nos. 4,069,812; 4,545,366; 4,848,319; 5,344,497; 5,496,414; 5,498,297; 5,505,789; 5,578,139; 6,031,179; 6,075,200; and in U.S. Patent Appln Publn. No. 2003/0201007. The linear arched Fresnel lens is prepared from the ionomer composition described herein.

Yet another preferred light concentrating article comprises a Fresnel lens as described in U.S. Pat. Nos. 5,118,361 and 5,217,539; in U.S. Patent Appln Publn. Nos. 2003/0075212 and 2004/0112424; in European Patent No. 1 892 771; and in Intl. Patent Appln Publn. Nos. WO2006/120475 and WO2007/041018. The Fresnel lens is prepared from the ionomer composition described herein.

Yet another preferred light concentrating article comprises a converging lens as described in U.S. Patent Appln Publn. Nos. 2005/0081909; 2006/0283495; 2007/0056626; 2008/0053515; and 2007/0095386; and in Intl. Patent Appln Publn. No. WO2007/093422, and wherein the converging lens is prepared from the ionomer composition described herein.

Further in this connection, the light concentrating article may be self-supporting, or it may be supported by a substrate. For example, a Fresnel lens made of polyacrylates, if of sufficient thickness, does not require a substrate. Alternatively, it may be preferable to use a substrate, for example a glass sheet, on the side of the Fresnel lens that is exposed to the atmosphere, in order to extend the useful life of the Fresnel lens. Other reasons for using substrates include providing dimensional stability of structural support to the light concentrating article. In addition, substrates may be transparent or opaque, depending on the purpose of the light concentrating article, for example. Apparently, transparent substrates are preferred for refracting light concentrating articles. In the case of reflecting light concentrating articles, however, transparent substrates may not be necessary, and opaque substrates may be preferred.

Suitable substrates include, without limitation, wood; metal; glass; organic polymers such as polystyrene, polyacrylates, polyesters, and polycarbonates; minerals such as slate, granite or marble; concrete; organic/inorganic composites; and the like. The thickness of the substrate will be selected according to the requirements of the end use. For example, polyester films having a thickness of several hundredths of a centimeter may be suitable substrates for flexible Fresnel lenses, whereas structural metal walls having a thickness of half a centimeter or more may be lined with curved mirrors.

The light concentrating article may be produced by any suitable process. For example, it may be formed by an injection molding process, an injection overmolding process, an extrusion process, a cast film or sheet process, a blown film or sheet process, or a profile extrusion process. Secondary forming processes, such as bending, stamping, machining and the like may also be used in forming the light concentrating articles. It may be necessary or desirable to use two or more of the processes or secondary processes to form the light concentrating article. Further information regarding suitable manufacturing processes is provided in U.S. Provisional Appln. No. 61/______, filed on Nov. 25, 2009 (Attorney Docket No. PP0128).

The light concentrating article described herein comprises an ionomer composition, which, in turn, comprises an ionomer. Ionomers are thermoplastic ionic copolymers that are known for use as solar cell encapsulant materials. See, for example, U.S. Pat. Nos. 5,476,553; 5,478,402; 5,733,382; 5,741,370; 5,762,720; 5,986,203; 6,114,046; 6,187,448; 6,353,042; 6,320,116; and 6,660,930; and U.S. Patent Appln. Publn. Nos. 2003/0000568; 2005/0279401; 2008/0017241; 2008/0023063; 2008/0023064; and 2008/0099064. In addition to their controllable clarity and ease of processing, ionomers have stable mechanical properties that render them suitable for use in light concentrating articles.

In particular, most thermoplastic materials are characterized by a correlation between the peak melting temperature (Tm), as measured by differential scanning calorimetry (DSC), and creep. Therefore, materials having a Tm less than about 60° C. have not been considered suitable candidates for use in light concentrating articles in solar cell modules. The assumption is that materials having a relatively low Tm will also be characterized by a low temperature of creep onset and a high level of creep. These properties will lead to unacceptably large deformation over the time period and under the conditions in which the solar cell module will be used. The deformed light concentrating articles will not function as efficiently, and therefore the solar cells will produce less electricity.

Surprisingly, this correlation does not apply with the same severity to the preferred ionomers. In fact, preferred ionomers are characterized by a significant, sign-inverted difference between the Tm and the temperature of creep onset. For example, it is expected that materials such as ionomers, which have peak melting temperatures in the range of 60° C. to 110° C., would also be subject to creep at temperatures less that the peak melting temperature, for example in the range of 45° C. to 85° C. Most polymers, in fact, begin to soften at temperatures that are below their melting points. It is also expected that the extent and rate of the creep would prevent ionomers from meeting the long-term stability requirements described above.

Advantageously, however, the temperature of onset of the ionomers' creep is higher than the peak melting temperature. In preferred ionomers, the temperature onset of creep is at least 5° C., at least 8° C. or at least 10° C. higher than the peak melting temperature.

Without wishing to be held to theory, it is hypothesized that the polyethylene segments of the ionomers have a degree of crystallinity that persists at temperatures that are greater than Tm. This is consistent with known trends in ionomer properties, for example the well-established correlation between decreasing acid level (complementarily increasing polyethylene level) and increasing Tm. Thus, the ionomer is not completely liquefied or amorphous, even though its thermodynamically defined and thermoanalytically measured melting point has been exceeded. Furthermore, in light of this hypothesis, any physical characteristic of the ionomer that tends to increase its crystallinity, or that tends to favor the persistence of tertiary structure at higher temperatures, will also increase the difference between the Tm and the temperature of creep onset.

It is also important to distinguish between creep under a significant applied force or load and creep under self-stress or low stress, in which the only load applied to the material is the force of its own weight or a very small additional force. It is further hypothesized that the rheological characteristics of the ionomers at temperatures above Tm approximate those of shear-thinning materials. In particular, the application of a small force to the ionomer may cause a deformation that is more than proportionately smaller compared to the deformation caused by the application of a larger force. It follows that the creep under self-stress or low stress of the preferred ionomers is unexpectedly decreased, compared to that of other thermoplastic materials.

Thus, counterintuitively, the preferred ionomers have low levels of creep at temperatures that are higher than their Tm. These creep levels and onset temperatures place the preferred ionomers squarely in the range of materials that are suitable for long-term use in light concentrating solar cell modules.

Turning now to chemical compositions, suitable ionomers are neutralized derivatives of a precursor acid copolymer comprising copolymerized units of an α-olefin having 2 to 10 carbon atoms and copolymerized units of an α,β-ethylenically unsaturated carboxylic acid having 3 to 8 carbons. The ionomers may comprise 40 wt % to 90 wt % of the copolymerized α-olefin and 10 wt % to 60 wt % of the copolymerized carboxylic acid, based on the total weight of the precursor acid copolymer. Preferably, the ionomers comprise 65 to 90 wt % or 70 to 85 wt % of the copolymerized α-olefin and 10 to 35 wt % or 15 to 30 wt % of the copolymerized carboxylic acid, and more preferably 75% to 80% of the copolymerized α-olefin and 20% to 25% of the copolymerized carboxylic acid.

Suitable α-olefin comonomers may include, but are not limited to, ethylene, propylene, 1-butene, 1-pentene, 1-hexene, 1-heptene, 3 methyl-1-butene, 4-methyl-1-pentene, and the like and mixtures of two or more thereof. Preferably, the α-olefin is ethylene.

Suitable α,β-ethylenically unsaturated carboxylic acid comonomers may include, but are not limited to, acrylic acids, methacrylic acids, itaconic acids, maleic acids, maleic anhydrides, fumaric acids, monomethyl maleic acids, and mixtures of two or more thereof. Preferably, the α,β-ethylenically unsaturated carboxylic acid is selected from acrylic acids, methacrylic acids, and mixtures of two or more thereof.

The precursor acid copolymers may further comprise copolymerized units of one or more other comonomer(s), such as unsaturated carboxylic acids having 2 to 10, or preferably 3 to 8 carbons, or derivatives thereof. Suitable acid derivatives include acid anhydrides, amides, and esters. Some suitable precursor acid copolymers further comprise an ester of the unsaturated carboxylic acid. Examples of suitable esters of unsaturated carboxylic acids include, but are not limited to, those that are set forth in U.S. patent application Ser. No. 12/610,678, filed on Nov. 2, 2009 (Attorney Docket No. PP0019). Examples of preferred comonomers include, but are not limited to, methyl acrylates, methyl methacrylates, butyl acrylates, butyl methacrylates, glycidyl methacrylates, vinyl acetates, and mixtures of two or more thereof. Preferably, however, the precursor acid copolymer does not incorporate other comonomers.

When a light concentrating article having low haze is desired, the precursor acid copolymer may have a melt flow rate (MFR) of about 1 to about 1000 g/10 min, preferably about 20 to about 900 g/10 min, more preferably about 60 to about 700 g/10 min, yet more preferably of about 100 to about 500 g/10 min, yet more preferably of about 150 to about 300 g/10 min, and most preferably of about 200 to about 250 g/10 min, as determined in accordance with ASTM method D1238 at 190° C. and 2.16 kg. The more preferable and most preferable MFR ranges of the precursor acid copolymers allow the resulting ionomer to have a high level of neutralization level, and in turn, low haze, high clarity, and excellent processability in the subsequent sheet production process or injection molding process.

When a measurable or significant level of haze is tolerable, however, the precursor acid copolymer preferably has a melt flow rate of about 60 g/10 min or less, more preferably about 45 g/10 min or less, yet more preferably about 30 g/10 min or less, or most preferably about 25 g/10 min or less, as measured by ASTM method D1238 at 190° C. and 2.16 kg. Again, in general, lower melt indices will favor lower creep.

The precursor acid copolymers may be polymerized as described in U.S. Pat. Nos. 3,404,134; 5,028,674; 6,500,888; or 6,518,365. They may be neutralized by any conventional procedure, such as those described in U.S. Pat. Nos. 3,404,134 and 6,518,365.

To obtain the ionomer useful in the ionomer composition of the light concentrating article, the precursor acid copolymer is preferably neutralized to a level of about 5% to about 90%, or preferably about 10% to about 60%, or more preferably about 20% to about 55%, or yet more preferably about 35% to about 55%, or most preferably about 40% to about 55%, based on the total carboxylic acid content of the precursor acid copolymers as calculated or measured for the non-neutralized precursor acid copolymers. The more preferable and most preferable neutralization ranges make it possible to obtain an ionomer sheet or molded article having one or more desirable properties such as low haze, high clarity, sufficient impact resistance, and good processability. Lower creep levels, however, are generally favored by higher neutralization levels.

Any cation that is stable under the conditions of polymer processing and solar cell fabrication is suitable for use in the ionomers. Ammonium cations are suitable, for example. Metal ions are preferred cations. The metal ions may be monovalent, divalent, trivalent, multivalent, or mixtures thereof. Useful monovalent metal ions include but are not limited to ions of sodium, potassium, lithium, silver, mercury, copper, and the like, and mixtures thereof. Useful divalent metal ions include but are not limited to ions of beryllium, magnesium, calcium, strontium, barium, copper, cadmium, mercury, tin, lead, iron, cobalt, nickel, zinc, and the like, and mixtures thereof. Useful trivalent metal ions include but are not limited to ions of aluminum, scandium, iron, yttrium, and the like, and mixtures thereof. Useful multivalent metal ions include but are not limited to ions of titanium, zirconium, hafnium, vanadium, tantalum, tungsten, chromium, cerium, iron, and the like, and mixtures thereof. It is noted that when the metal ion is multivalent, complexing agents such as stearate, oleate, salicylate, and phenolate radicals may be included, as described in U.S. Pat. No. 3,404,134. The metal ions are preferably monovalent or divalent metal ions. In one preferred ionomer, the metal ions are selected from sodium, lithium, magnesium, zinc, potassium and mixtures thereof. In another preferred ionomer, the metal ions are selected from sodium, zinc and mixtures thereof. Zinc is a preferred cation when resistance to the incursion of moisture is required.

The ionomer used in the light concentrating article may have a MFR of 0.75 to about 20 g/10 min, preferably about 1 to about 10 g/10 min, yet more preferably about 1.5 to about 5 g/10 min, and most preferably about 2 to about 4 g/10 min, as determined in accordance with ASTM method D1238 at 190° C. and 2.16 kg. Surprisingly, some of these ionomers have lower haze and higher clarity in combination with lower moisture absorption then those found within the art at equal melt viscosity, as measured, for example, by MFR. Generally, lower creep is promoted by lower melt indices.

Some preferred ionomer compositions are easily processable into low haze, high clarity ionomer articles. In particular, the low haze, high clarity ionomer articles are provided by ionomer compositions with a high neutralization level, such as the most preferable neutralization level of from about 40 to about 55% described above. It is well known that the MFR of an ionomer is reduced (the ionomer becomes more viscous) as its neutralization level is increased. As described herein, the high MFR precursor acid copolymers allow the resulting ionomer to attain high neutralization levels while maintaining good processability during melt processes such as sheeting or molding. For example, when an ionomer has a MFR below about 0.75 g/10 min, it can become difficult to process through extrusion casting and injection molding operations, and heat generated by shear stress may cause significant thermal degradation. As re-grind is common in both sheeting and injection molding process, maintaining the ionomer at a relatively higher MFR level (e.g., not less than about 0.75 g/10 min) is desirable.

In one preferred light concentrating article, the ionomer(s) used in the ionomer composition are selected from among the low haze, high clarity ionomers described in U.S. patent application Ser. Nos. 12/610,678 (Attorney Docket No. PP0019), cited above, or 12/610,881, filed on Nov. 2, 2009 (Attorney Docket No. PP0055).

Alternatively, it may be advantageous for the light concentrating article to have a measurable level of haze. For example, a Fresnel lens having an appreciable level of haze will cast light on the solar cells more evenly that a Fresnel lens having an insignificant level of haze. In general, ionomers that include lower levels of copolymerized acid, or that include optional copolymerized esters, or that are synthesized under multiphase reaction conditions (see U.S. patent application Ser. No. 12/610,678 (Attorney Docket No. PP0019), cited above) tend to have appreciable levels of haze. Synthesis under multiphase conditions promotes the sequential reaction of like comonomers. In this way, long runs of polyethylene are formed in the polymer chain, and this phenomenon promotes the tendency of the polyethylene segments to crystallize. Increased crystallinity favors both increased haze and lower creep, particularly at temperatures higher than the ionomer's Tm. In addition, other strategies for increasing haze include cooling the ionomer composition slowly to promote crystallinity in the ionomer's poly(ethylene) segments, lower neutralization levels, including other polymers that have higher haze in the ionomer composition, and adding filler to the ionomer composition.

The ionomer compositions may further include one or more additives. For example, initiators such as dibutyltin dilaurate may also be present in the ionomeric composition at a level of about 0.01 to about 0.05 wt %, based on the total weight of the ionomer composition. In addition, if desired, inhibitors, such as hydroquinone, hydroquinone monomethyl ether, p-benzoquinone, and methylhydroquinone, may be added for the purpose of enhancing control to the reaction and stability. Typically, the inhibitors would be added at a level of less than about 5 wt %, based on the total weight of the composition.

The ionomer compositions may further contain other additives that effectively reduce the melt flow of the resin, and that may be present in any amount that permits production of thermoset articles. That is, the initiators and other melt-flow reducing additives may be present in any amount that does not result in an ionomer composition that is intractable, or one that cannot be processed in the melt. The use of such additives will enhance the upper end-use temperature, reduce creep and generally increase the dimensional stability of the light-concentrating article derived therefrom. Typically, the end-use temperature of the ionomer composition may be increased by up to about 20 to 70° C., resulting in an end-use temperature of 120° C. or greater.

Typical effective melt flow reducing additives are organic peroxides, such as 2,5-dimethylhexane-2,5-dihydroperoxide, 2,5-dimethyl-2,5-di(tert-butylperoxy)hexane-3, di-tert-butyl peroxide, tert-butylcumyl peroxide, 2,5-dimethyl-2,5-di(tert-butylperoxy)hexane, dicumyl peroxide, alpha, alpha′-bis(tert-butyl-peroxyisopropyl)benzene, n-butyl-4,4-bis(tert-butylperoxy) valerate, 2,2-bis(tert-butylperoxy)butane, 1,1-bis(tert-butyl-peroxy) cyclohexane, 1,1-bis(tert-butylperoxy)-3,3,5-trimethyl-cyclohexane, tert-butyl peroxybenzoate, benzoyl peroxide, and the like and mixtures combinations thereof. Preferably the organic peroxides decompose at a temperature of about 100° C. or higher to generate radicals. More preferably, the organic peroxides have a decomposition temperature which affords a half life of 10 hours at about 70° C. or higher to provide improved stability for blending operations. The organic peroxides may be added at a level of about 0.01 to about 10 wt %, or preferably, about 0.5 to about 3 wt %, based on the total weight of the ionomer composition.

Silanes are additives that promote adhesion and cross-linking. Examples of silane coupling agents that are useful in the ionomer compositions include, but are not limited to, γ-chloropropylmethoxysilane, vinyltrimethoxysilane, vinyltriethoxysilane, vinyltris(β-methoxyethoxy)silane, γ-vinylbenzylpropyl trimethoxysilane, N-β-(N-vinylbenzylaminoethyl)-γ-aminopropyltrimethoxysilane, γ-methacryloxypropyltrimethoxysilane, vinyltriacetoxysilane, γ-glycidoxypropyl trimethoxysilane, γ-glycidoxypropyl triethoxysilane, β-(3,4-epoxycyclohexyl)ethyltrimethoxysilane, vinyltrichlorosilane, γ-mercaptopropylmethoxysilane, γ-aminopropyltriethoxy silane, N-β-(aminoethyl)-γ-aminopropyltrimethoxysilane. Also suitable are the silane coupling agents described in U.S. Patent Appln. Publn. Nos. 2007/0267059; 2008/0108757 and 2008/0169023. More preferred are ethoxysilanes, including dimethoxysilanes (such as (CH₃O)₂SiRR′), diethoxysilanes (such as (CH₃CH₂O)₂SiRR′) and triethoxysilanes (such as (CH₃CH₂O)₃SiR), and, more generally, dialkoxysilanes (such as (RO)(R′O)SiR″R′″). Other suitable silanes are described in U.S. Patent Publn. Nos. 2006/352,789 and 1999/320,995. Moreover, two or more suitable silanes may be used in combination in the ionomeric compositions. The silane coupling agents are preferably incorporated in the ionomer composition at a level of about 0.01 to about 5 wt %, or more preferably about 0.05 to about 1 wt %, based on the total weight of the ionomer composition.

In addition, initiator(s) alone, peroxide(s) alone, silane(s) alone, or combinations of two or more of at least one silane, at least one peroxide and at least one initiator may be used in the ionomeric compositions.

In this connection, and as discussed above, dimensional stability is an important property of the components of a solar cell. Therefore, in some ionomer compositions, it is preferred to use a crosslinking agent to increase the dimensional stability of the light concentrating article. For the sake of process simplification and ease, however, it may be preferred that cross-linking additives be omitted from the ionomer compositions.

Other additives of note include thermal stabilizers, UV absorbers and hindered amine light stabilizers. Suitable and preferred additives, levels of the additives in ionomer compositions, and methods of incorporating the additives into the compositions are described at length in U.S. patent application Ser. No. 12/610,678 (Attorney Docket No. PP0019), cited above.

The ionomer composition may also contain one or more other additives known in the art. The additives may include, but are not limited to, processing aids, flow enhancing additives, lubricants, pigments, dyes, flame retardants, impact modifiers, nucleating agents, anti-blocking agents such as silica, UV stabilizers, dispersants, surfactants, chelating agents, other coupling agents, and reinforcement additives, such as glass fiber, fillers, and the like, and mixtures or combinations of two or more conventional additives. These additives are described in the Kirk Othmer Encyclopedia of Chemical Technology, 5^{th} Edition, John Wiley & Sons (New Jersey, 2004), for example. Moreover, the optional incorporation of such conventional ingredients into the compositions can be carried out by any known process. This incorporation can be carried out, for example, by dry blending, by extruding a mixture of the various constituents, by the masterbatch technique, or the like. See, again, the Kirk-Othmer Encyclopedia.

In summary, preferred concentrator solar cell modules include those having one or more of the following characteristics:
1. The ionomer has a melt flow rate of about 0.75 to about 20 g/10 min and the precursor α-olefin carboxylic acid copolymer has a melt flow rate of about 1 to about 1000 g/10 min, or about 60 to about 700 g/10 min, as determined in accordance with ASTM D1238 at 190° C., 2.16 kg.
2. The carboxylic acid groups present in the precursor α-olefin carboxylic acid copolymer have been at least partially neutralized and comprise one or more metal ions that are selected from the group consisting of sodium, lithium, magnesium, zinc, and potassium.
3. The carboxylic acid groups present in the precursor α-olefin carboxylic acid copolymer have been neutralized and comprise a mixture of about 5 to about 95 mole %, or about 55 to about 70 mole %, of sodium ions, with the balance being zinc ions, based on the total number of moles of carboxylate groups in the ionomer.
4. The temperature of onset of the ionomers' creep is higher than the peak melting temperature.
5. The temperature onset of the ionomer's creep is at least 5° C., at least 8° C. or at least 10° C. higher than the peak melting temperature.
6. The ionomer composition comprises a low-haze, high clarity ionomer.
7. The ionomer composition has an appreciable level of haze.
8. The solar cell(s) are selected from the group consisting of wafer-based solar cells and thin film solar cells.
9. The wafer-based solar cell(s) are selected from the group consisting of crystalline silicon (c-Si), multi-crystalline silicone (mc-Si), GaAs based solar cells.
10. The thin film solar cell(s) are selected from the group consisting of amorphous silicon (a-Si), microcrystalline silicon (μc-Si), cadmium telluride (CdTe), copper indium selenide (CIS), copper indium/gallium diselenide (CIGS), light absorbing dyes, and organic semiconductor based solar cells.
11. The light concentrating article(s) used in the concentrator solar cell module are in the form of a reflective or a refractive optical system, or comprise a combination of reflective and refractive optical systems.
12. The reflective optical system is selected from the group consisting of a reflective mirror comprising the ionomer composition, a reflective parabaloid comprising the ionomer composition, a reflective dish comprising the ionomer composition, and a linear parabolic trough comprising the ionomer composition. Moreover, the refractive optical system is selected from the group consisting of a refractive lens comprising the ionomer composition and a secondary light concentrating article, such as a dichroic filter, that comprises the ionomer composition.
13. The reflective optical system is metallized to enhance the amount of reflected light.
14. The refractive lens is derived from imaging optics.
15. The refractive lens is selected from the group consisting of a shaped incident encapsulant layer, a cover slide comprising a converging lens, a coverglass comprising a converging lens, a converging lens, a simple lens, a complex lens, a biconvex lens, a plano-convex lens, a positive meniscus lens, a plano-concave lens, an inflatable lens, a Fresnel lens, a linear Fresnel lens, a linear arched Fresnel lens, a point focus Fresnel lens, and a combination of two or more thereof.
16. The refractive lens is derived from non-imaging optics.
17. The refractive lens also comprises an antireflective coating.
18. The antireflective coating comprises a material selected from MgF2, fluoropolymer, fluoroelastomer, and mixtures thereof.

The following examples are provided to describe the invention in further detail. These examples, which set forth a preferred mode presently contemplated for carrying out the invention, are intended to illustrate and not to limit the invention.

### EXAMPLES

The ionomer resins used in Examples E1 to E25 and Comparative Examples CE1 to CE4 are described in Table 1.

TABLE 1

| | | Melt Index | | |
|---|---|---|---|---|
| | | Prior to | Neutralization | Melt Index |
| | Comonomer | Neutralization² | Level (%)/ | of Ionomer² |
| Name | Composition¹ | (g/10 min) | Cation | (g/10 min) |
| ION A | 15 | 225 | 51/Na⁺ | 4.5 |
| ION B | 14.9 | 470 | 68/Na⁺ | 2.7 |
| ION C | 15 | 60 | 56/Na⁺ | 0.9 |
| ION D | 18.9 | 210 | 45/Na⁺ | 4.4 |
| ION E | 19 | 60 | 37/Na⁺ | 2.6 |
| ION F | 23.2 | 270 | 26/Na⁺ | 16 |
| ION G | 23.2 | 270 | 33/Na⁺ | 8.2 |
| ION H | 21.7 | 23 | 25/Na⁺ | 1.8 |
| ION I | 19.8 | 350 | 49/Na⁺ | 4.5 |
| ION J | 21.7 | 350 | 53/Na⁺ | 2.5 |
| ION K | 15 | 25 | 17/Zn²⁺ | 5.9 |
| ION L | 19 | 250 | 39/Zn²⁺ | 4 |
| ION M | 23.2 | 270 | 34.9/Zn²⁺ | 6.6 |
| ION N | 19 | 60 | 36/Zn²⁺ | 1 |
| ION O | 21.7 | 23 | 15/Zn²⁺ | 5.4 |
| ION P | 21.7 | 23 | 25/Zn²⁺ | 1.7 |
| ION Q | 21.7 | 23 | 15/Na⁺ | 3.4 |
| ION R | 21.7 | 23 | 20/Na⁺ | 2.3 |
| ION S | 21.7 | 23 | 26/Na⁺ | 1.8 |
| ION T | 21.7 | 23 | 30/Na⁺ | 0.9 |
| ION U | 23.2 | 270 | 14/Na⁺ | 40 |
| ION V | 23.2 | 270 | 43/Na⁺ | 3.2 |
| ION W | 23.2 | 270 | 52/Na⁺ | 0.8 |

¹Values listed are weight percentages of copolymerized methacrylic acid, based on the total weight of the copolymer before neutralization. The remainder of the copolymer is copolymerized ethylene.
²Measured according to ASTM Method No. D1238 at a temperature of 190° C. and under a weight of 2.16 kg.

### Comparative Examples CE1 to CE3 and Examples E1 to E7

Several ionomer compositions were fed into a Model 150-6 HPM injection molding machine (Taylor's Industrial Services, Mount Gilead, Ohio), with the melt temperature maintained in the range of 130° to 200° C., which is more than about 10° C. above the ionomer melting points. The mold cycle time was approximately 90 seconds. Thin rectangular parts (125×75×3 mm) and thick rectangular parts (125×45×20 mm) were then ejected from the mold, placed on a table and allowed to air cool to room temperature (about 22±3° C.).

The haze of the thin rectangular parts was measured in accordance with ASTM method D 1003-07 through the 3 mm thickness on a HunterLab Color Quest XE haze meter (Hunter Associates Laboratory, Reston, Va.) and the measurements are reported below in Table 1 as “Haze Air Cool.”

The thick rectangular parts were visually inspected. The clarity of each of the samples was ranked relative to that of the other samples. The clarity ratings ranged from 1 (highest clarity) to 5 (lowest clarity). The results are summarized below in Table 1 as “Clarity Air Cool.”

Next, the thin rectangular parts were re-heated in an air oven to a temperature of 125° C. for 90 minutes. They were cooled to room temperature at a controlled, slower rate of 0.1° C./minute. These conditions are intended to mimic the rate at which thick molded articles are cooled in air to ambient temperature. The haze of the re-heated parts was measured once more by the same method, and the measurements are reported below in Table 2 as “Haze Slow Cool.”

TABLE 2

| | |
|---|---|
| Haze (%) | Clarity |

| Example | Ionomer | Air Cool | Slow Cool | (Air Cool) |
|---|---|---|---|---|
| CE1 | ION A | 2.2 | 70.6 | 5 |
| CE2 | ION B | 0.6 | 56.2 | 5 |
| CE3 | ION C | 4.3 | 52.6 | 3 |
| E1 | ION D | 0.9 | 16.9 | 2 |
| E2 | ION E | 1.7 | 13.5 | 2 |
| E3 | ION F | 1.5 | 11.7 | 2 |
| E4 | ION G | 0.8 | 9.4 | 1 |
| E5 | ION H | 3 | 6.7 | 1 |
| E6 | ION I | 0.6 | 5 | 2 |
| E7 | ION J | 0.6 | 0.3 | 1 |

### Comparative Example CE4 and Examples E8 to E25

Various types of ionomer resins were fed into a 25 mm diameter Killion extruder under the temperature profile listed in Table 3. The resins were extrusion cast into ionomer sheets under the following conditions. First, the polymer throughput was controlled by adjusting the screw speed to maximum throughput. The extruder fed a 150 mm slot die with a nominal gap of 2 mm. The as-cast sheet was fed onto a 200 mm diameter polished chrome chill roll held at a temperature of between 10° C. and 15° C. and rotating at 1 to 2 rpm. The ionomer sheets had a nominal thickness of 0.76 mm (0.030 in). They were removed from the extrusion line and cut into 300×300 mm squares. The moisture level of the ionomer sheets was kept below 0.06% by weight by minimizing exposure to ambient conditions, which included a relative humidity (RH) of about 35%.

TABLE 3

| Extruder Zone | Temperature (° C.) |
|---|---|
| Feed | Ambient |
| Zone 1 | 100-170 |
| Zone 2 | 150-210 |
| Zone 3 | 170-230 |
| Adapter | 170-230 |
| Die | 170-230 |

Glass laminates were prepared from each of the ionomer sheets. Annealed glass sheets (100×100×3 mm) were washed with a solution of trisodium phosphate (5 g/l) in de-ionized water at 50° C. for 5 min, then rinsed thoroughly with de-ionized water and dried. Three layers of each ionomer sheet were stacked together and placed between two lites of glass sheet to form a pre-lamination assembly. The nominal thickness of the interlayer was 2.28 mm.

The pre-lamination assembly was taped together with polyester tape in several locations to maintain the relative positioning of each layer. A nylon fabric strip was placed around the periphery of the assembly to facilitate air removal from within the layers. The assembly was placed inside a nylon vacuum bag and sealed. A vacuum was applied so that the air pressure inside the bag was reduced to below 50 millibar absolute. The bagged assembly was then placed for 30 min in a convection air oven whose temperature was held at 120° C. A cooling fan was then used to cool the assembly down to near room temperature. The assembly was disconnected from the vacuum source, and the bag was removed to yield a fully pre-pressed assembly of glass and interlayer. The assembly, although hermetically sealed around the periphery, exhibited some bubbles, signifying that certain areas that had not been fully bonded.

The assembly was then placed into an air autoclave. The temperature and pressure in the autoclave were increased from ambient to 135° C. at 13.8 bar over 15 min. This temperature and pressure was held for 30 min, and then the temperature was decreased to 40° C. at Cooling Rate A of 2.5° C./min. Concomitantly, by operation of Gay-Lussac's Law and by venting over a period of 15 min, the pressure inside the autoclave was reduced to ambient. Thereafter, the same laminate was heated to 120° C. in an oven and maintained at such temperature for 2 to 3 hours before it was slowly cooled (e.g., at Cooling Rate B of 0.1° C./min) to room temperature and then tested for haze.

The finished laminates were removed from the autoclave, and their haze was measured. First, the glass laminates were thoroughly cleaned using Windex® glass cleaner and lintless cloths. They were inspected to ensure that they were free of bubbles and other defects that might interfere with the accuracy of the optical measurements. The laminates' haze was measured using a Gardner Hazemeter (BYK-Gardner USA, Columbia, Md.) in accord with American National Standard (ANSI Z26.1-1966) “Safety Code for Safety Glazing Materials for Glazing Motor Vehicles Operating on Land Highways” test section 5.17 and 5.18 along with FIGS. 5 and 6 detail the appropriate method and instrumental setup to measure the haze level of a glazing material. Haze standards which are traceable to the National Bureau of Standards (now NIST) were used to ensure that the instrument was well-calibrated and operating properly. The results of the measurements of the laminates are set forth in Table 4.

These results demonstrate that, in general, as the cooling rate decreases, the haze increases and therefore the clarity of the laminate decreases. The results also demonstrate that ionomers having higher acid levels (i.e., about 18 to about 30 wt %, preferably about 20 to about 25 wt %, more preferably about 21 to about 24 wt %) and comparable neutralization levels exhibit lower haze or better clarity compared to ionomers that have lower acid levels (i.e., 15 wt %).

TABLE 4

Haze (%)

| Example | Ionomer | Cooling Rate A | Cooling Rate B |
|---|---|---|---|
| CE4 | ION K | 31.5 | 98.3 |
| E8 | ION L | 11.6 | 69.5 |
| E9 | ION M | 6.3 | 52.6 |
| E10 | ION N | 6.4 | 27.4 |
| E11 | ION O | 2.2 | 14.8 |
| E12 | ION P | 1.4 | 10.3 |
| E13 | ION E | 1 | 22.5 |
| E14 | ION I | 0.7 | 1.7 |
| E15 | ION Q | 1.5 | 12.7 |
| E16 | ION R | 1.1 | 7.2 |
| E17 | ION H | 0.9 | 4.4 |
| E18 | ION S | 0.8 | 5.2 |
| E19 | ION T | 1 | 3.3 |
| E20 | ION J | 0.6 | 0.6 |
| E21 | ION U | — | 38.2 |
| E22 | ION F | — | 7.7 |
| E23 | ION G | — | 8.1 |
| E24 | ION V | 0.7 | 1.1 |
| E25 | ION W | — | 0.9 |

### Examples E26 to E32

Slides of float glass (Krystal Klear Solar Glass™ from AFG Industries Inc., Kingsport, Tenn.) measuring 2 in×2 in (5.1 cm×5.1 cm) were immersed for five minutes in an ethanolic solution of 3-aminopropyltrimethoxy-silane (about 5 drops in 100 g of 95% ethanol, resulting in an aminosilane concentration of approximately 0.01%). The slides were removed from the solution, rinsed with isopropanol, and dried under a flow of high pressure nitrogen gas. The treated slides were further dried in an oven at 100° C. for 30 minutes.

Uncoated films were prepared from sheets of Surlyn® 9120, available from E.I. du Pont de Nemours and Co., Wilmington, Del. (hereinafter “DuPont”). The Surlyn® sheets were dried under vacuum for 48 hours at 50° C., then calendered to a thickness of 5 mil (0.127 mm) using a Model XRL-120 Hot Roll Laminator (Western Magnum Corporation, El Segundo, Calif.) at 155° C. and 19 psi (0.13 MPa). The calendered films were cut into squares measuring 2 in by 2 in (5.1 cm×5.1 cm).

Coated films were prepared by drying the Surlyn® 9120 sheets at 40° C. under vacuum for 2 weeks, then calendaring them to a thickness of 5 mils (0.127 mm) by the same procedure used for the uncoated films. A fluoropolymer-based antireflective coating solution was prepared by dissolving 2 g Viton® GF-2005 fluoroelastomer (DuPont), 0.2 g Irgacure®-651 (Ciba Specialty Chemicals) and 0.2 g triallyl isocyanurate (Aldrich) in 32 g propyl acetate, then filtering the solution through a 0.45 μm Teflon® PTFE membrane filter. The calendered Surlyn® films were coated with the anti-reflective coating solution a using a Mini-Labo coater (Yasui Seiki Co., Bloomington, Ind.) under the following conditions: #200 MG roll @ 6.5 rpm, line speed=0.5 m/min, dryer off and no airflow. The coatings were uniform in thickness as determined by spectral reflectance measurements using a thin film analyzer (Model F20-EXR from Filmetrics, Inc., San Diego, Calif.; Rmin=640 to 650 nm).

The coated films were cured immediately after coating. First, a film measuring 4 in×24 in (10.2 cm×61.2 cm) was placed on an aluminum sample holder that had been warmed on a hotplate at 75° C. This assembly was passed twice through a Model SB614 Benchtop Conveyor UV curing unit (Fusion UV Systems, Gaithersburg, Md.) at a speed of 0.7 mm/min. The frequencies and intensities of the radiation are set forth in Table 5. The cured films were cut into squares measuring 2 in by 2 in (5.1 cm×5.1 cm) and stored under ambient conditions.

TABLE 5

| UV-A | | UV-B | | UV-C | | UV-V | |
|---|---|---|---|---|---|---|---|
| J/cm2 | W/cm2 | J/cm2 | W/cm2 | J/cm2 | W/cm2 | J/cm2 | W/cm2 |
| 0.561 | 0.200 | 0.370 | 0.128 | 0.070 | 0.022 | 0.269 | 0.100 |

Pre-lamination assemblies were prepared by stacking the Surlyn® 9120 films against the tin side of the treated float glass slides. The uncoated side of the coated Surlyn® films was in contact with the glass side. Each pre-lamination assembly was placed in a sample holder assembly under vacuum. The loaded sample holder assembly was inserted into a Carver press that was heated to 150° C. Once the temperature of the press re-stabilized at 150° C., pressure (less than 1000 psi (6.89 MPa)) was applied to the sample holder assembly and held for 15 minutes. The heating was discontinued and the press was cooled with water. The sample assembly was removed from the press after it had cooled to 60° C.

The Surlyn®/glass laminates were embossed with a Fresnel lens pattern. An embossing template was stacked against the Surlyn® layer, and this assembly was processed in a Carver press according to the procedure outlined above for lamination, except that a pressure of less than 500 psi (3.45 MPa) was applied for 5 min. The templates and temperatures used for embossing each Example are set forth in Table 6.

TABLE 6

| Example | Coated (C) or | Embossing | Embossing |
|---|---|---|---|
| No. | Uncoated (U) | Template | Temperature, C. ° |
| E26 | U | AB | 90 |
| E27 | U | FL | 90 |
| E28 | U | FL | 95 |
| E29 | U | FL | 100 |
| E30 | C | AB | 100 |
| E31 | C | FL | 90 |
| E32 | C | FL | 95 |

³ AB is an aluminum block etched with a pattern consisting of linear triangular grooves with alternating peak heights of 60 and 100 micrometers and bases that are 500 micrometers in width. FL is a commercially available plastic pocket-sized Fresnel lens.

The surface patterns of Example Nos. E26, E27, E29 and E30 were measured as profile scans using a DekTak profilometer (Veeco Instruments, Inc., Plainview, N.Y.). The surface patterns of the Fresnel lens (before and after embossing) and of the aluminum block were also measured. The conditions of the profile scans were: stylus type: radius, 12.5 μm; scan length: 5000 μm; resolution: 1.111 μm/sample; stylus force: 3 mg; scan length: 5000 μm; samples: 4500; duration: 15 sec; measurement range: 2620 kÅ.

The profile measurements revealed that the inverse structure of the aluminum mold was replicated with good precision on the Surlyn®/glass laminated samples. The inverse pattern of the Fresnel lens, however, was not replicated with the same degree of precision. Moreover, distortion is observed in the surface pattern of the Fresnel lens after embossing. It is hypothesized that the Fresnel lens was made of poly(methyl methacrylate) or another material that might be subject to distortion under the embossing conditions.

Confocal microscopy further confirmed the precision with which the Fresnel lens pattern was transferred in Example E27.

In summary, Examples E26 to E32 demonstrate that micro-patterns, including optical Fresnel patterns, can be accurately embossed onto Surlyn®/glass laminates at relatively low pressures and temperatures.

While certain of the preferred embodiments of the present invention have been described and specifically exemplified above, it is not intended that the invention be limited to such embodiments. Rather, it is to be understood that even though numerous characteristics and advantages of the present invention have been set forth in the foregoing description, together with details of the structure and function of the invention, the disclosure is illustrative only, and changes may be made in detail, especially in matters of shape, size and arrangement of parts within the principles of the invention to the full extent indicated by the broad general meaning of the terms in which the appended claims are expressed.

What is claimed is:

1. A concentrator solar cell module comprising one or a plurality of solar cells and at least one light concentrating article, wherein:
the light concentrating article is capable of concentrating about 1.02 to about 2000 suns of solar energy onto the solar cells;
the at least one light concentrating article comprises an ionomer composition, and the ionomer composition comprises or is prepared from an ionomer; the ionomer has a temperature onset of creep and a peak melting temperature; and the temperature onset of creep is at least 5° C. higher than the peak melting temperature.

2. The concentrator solar cell module of claim 1, wherein the temperature onset of creep is at least 8° C. higher than the peak melting temperature.

3. The concentrator solar cell module of claim 1, wherein the temperature onset of creep is at least 10° C. higher than the peak melting temperature.

4. The concentrator solar cell module of claim 1, wherein the solar cells are selected from the group consisting of wafer-based solar cells and thin film solar cells.

5. The concentrator solar cell module of claim 4, wherein the wafer-based solar cells are selected from the group consisting of crystalline silicon (c-Si), multi-crystalline silicon (mc-Si), poly-crystalline silicon (poly-Si), ribbon silicon and GaAs based solar cells.

6. The concentrator solar cell module of claim 4, wherein the thin film solar cells are selected from the group consisting of amorphous silicon (a-Si), microcrystalline silicon (μc-Si), cadmium telluride (CdTe), copper indium selenide (CIS), copper indium/gallium diselenide (CIGS), light absorbing dyes, and organic semiconductor based solar cells.

7. The concentrator solar cell module of claim 1, wherein the light concentrating article acts as a reflective optical system, a refractive optical system, or both a reflective and a refractive optical system.

8. The concentrator solar cell module of claim 7, wherein the reflective optical system comprises the ionomer composition and is selected from the group consisting of a reflective mirror, a reflective parabaloid, a reflective dish, and a linear parabolic trough.

9. The concentrator solar cell module of claim 7, wherein the refractive optical system comprises the ionomer composition and is selected from the group consisting of a refractive lens and a dichroic filter.

10. The concentrator solar cell module of claim 9, wherein the refractive lens is derived from imaging optics.

11. The concentrator solar cell module of claim 9, wherein the refractive lens is selected from the group consisting of a shaped incident encapsulant layer, a cover slide comprising a converging lens, a cover glass comprising a converging lens, a converging lens, a simple lens, a complex lens, a biconvex lens, a plano-convex lens, a positive meniscus lens, a plano-concave lens, an aspheric lens, an inflatable lens, a Fresnel lens, a linear Fresnel lens, a linear arched Fresnel lens, a point focus Fresnel lens, a segmented Fresnel lens, and a combination of two or more of any of these lenses.

12. The concentrator solar cell module of claim 9, wherein the refractive lens is derived from non-imaging optics.

13. The concentrator solar cell module of claim 9, wherein at least a portion of the refractive lens is coated with an antireflective coating.

14. The concentrator solar cell module of claim 13, wherein the antireflective coating comprises a material selected from MgF₂, a fluoropolymer, a fluoroelastomer, and mixtures of two or three of MgF₂, the fluoropolymer, and the fluoroelastomer.

15. A concentrator solar cell module comprising one or a plurality of solar cells and at least one light concentrating article, wherein,
(A) the light concentrating article is capable of concentrating about 1.02 to about 2000 suns of solar energy onto the solar cells;
(B) the at least one light concentrating article comprises an ionomer composition, and the ionomer composition comprises or is prepared from an ionomer; the ionomer comprises carboxylate groups and cations and is the product of a neutralization of a precursor α-olefin carboxylic acid copolymer; the precursor α-olefin carboxylic acid copolymer comprises (i) copolymerized units of an α-olefin having 2 to 10 carbons and (ii) about 18 to about 30 wt % of copolymerized units of an α,β-ethylenically unsaturated carboxylic acid having 3 to 8 carbons, based on the total weight of the α-olefin carboxylic acid copolymer; and about 5% to about 90% of the total content of the carboxylic acid groups present in the precursor α-olefin carboxylic acid copolymer are neutralized to form the ionomer.

16. The concentrator solar cell module of claim 15, wherein the precursor α-olefin carboxylic acid copolymer comprises about 20 to about 25 wt % of copolymerized units of the α,β-ethylenically unsaturated carboxylic acid.

17. The concentrator solar cell module of claim 15, wherein about 20% to about 55% of the total content of the carboxylic acid groups present in the precursor α-olefin carboxylic acid copolymer are neutralized.

18. The concentrator solar cell module of claim 15, wherein the ionomer has a melt flow rate of about 0.75 to about 20 g/10 min and the precursor α-olefin carboxylic acid copolymer has a melt flow rate of about 1 to about 1000 g/10 min, as determined in accordance with ASTM D1238 at 190° C. and under a weight of 2.16 kg.

19. The concentrator solar cell module of claim 15, wherein the cations include ions of sodium, ions of zinc, or ions of both sodium and zinc.

20. The concentrator solar cell module of claim 19, wherein the cations comprise about 55 to about 70 equiv % of sodium ions and, complementarily, about 30 to about 45 equiv % of zinc ions.
